(19) United States
(12) Patent Application Publication
(10) Pub. No.: US 2010/0319758 A1
(43) Pub. Date: Dec. 23, 2010

(54) PHOTOVOLTAIC DEVICE

(75) Inventor: Takashi IKUNO, Nisshin-shi (JP)

Correspondence Address: OLIFF & BERRIDGE, PLC, P.O. BOX 320850, ALEXANDRIA, VA, 22320-4850, US

(73) Assignee: KABUSHIKI KAISHA TOYOTA CHUO KENKYUSHO, Aichi-gun (JP)

(21) Appl. No.: 12/816,622

(22) Filed: Jun. 16, 2010

(30) Foreign Application Priority Data
Jun. 23, 2009 (JP) 2009-148726

(51) Int. Cl. H01L 31/02

(52) U.S. Cl. 136/252; 977/762

(57) ABSTRACT

A photovoltaic device comprising a substrate having a flat surface; semiconductor nanowires which are densely arrayed on the flat surface and tapered from the flat surface; and a semiconductor layer which fills gaps between the semiconductor nanowires and has a different carrier type from that of the semiconductor nanowires.

### BACKGROUND OF THE INVENTION

1. Field of the Invention

The present invention relates to a photovoltaic device.

2. Related Background Art

Semiconductor nanostructures are attracting attention as building blocks for the next generation solar cells. For example, an extremely thin absorber (ETA) solar cell is under consideration (K. Ernst, A. Belaidi, R. Konenkamp, Semicond. Sci. Technol. 2003, Vol. 18; C. Levy-Clement, R. Tena-Zaera, M. A. Ryan, A. Katty, G. Hodes, Adv. Mater. 2005, Vol. 17, p. 1512; R. Tena-Zaera, A. Katty, S. Bastide, C. Levy-Clement, B. O'Regan, V. Munoz-Sanjose, Thin Solid Films, 2005, Vol. 483, p. 372). An ETA solar cell is comprised of a wide bandgap semiconductor nanostructure, and an ETA which is coated on the nanostructure. A three-dimensional solar cell using a two-dimensionally arrayed cylindrical light absorption layer was also proposed (M. Nanu, J. Schoonman, A. Gooseens, Adv. Mater., 2004, Vol. 16, p. 453; M. Nanu, J. Schoonman, A. Gooseens, Adv. Mater., 2005, Vol. 15, p. 95; Y. B. Tang, Z. H. Chen, H. S. Song, C. S. Lee, H. T. Cong, H. M. Cheng, W. J. Zhang, I. Bello, S. T. Lee, Nano. Lett., 2008, Vol. 8, p. 4191; L. Tasakalakos, J. Balch, J. Fronheiser, B. A. Korevaar, O. Sulima, J. Rand, Appl. Phys. Lett., 2007, Vol. 91, p. 233117).

FIG. 1 is a cross-sectional view depicting an example of a conventional thin film type or bulk junction type photovoltaic device. The photovoltaic device shown in FIG. 1 is comprised of a substrate 1, a p-type semiconductor layer 20 and n-type semiconductor layer 30, and these are layered in this order. In FIG. 1, the arrow 25 indicates a flow of minority carriers, and the arrow 35 indicates a flow of majority carriers. In the photovoltaic device of FIG. 1, the minority carriers (electrons) generated in the p-type semiconductor layer 20 move to the interface of the p-type semiconductor layer 20 and the n-type semiconductor layer 30, where carrier separation occurs, and electrons move into the n-type semiconductor layer. At this time, the minority carriers generated near the substrate 1 have the disadvantage in terms of extraction efficiency of carrier, since the probability of carrier recombination before reaching the interface is high.

FIG. 2 shows a photovoltaic device having a cylindrical p-type semiconductor layer 20. In the case of the photovoltaic device in FIG. 2, some improvement is expected in terms of extraction efficiency of carrier, since the moving distance of the minority carriers generated in the p-type semiconductor layer 20 to the interface is short.

However in order to further improve the photo-to-electric conversion efficiency, it is demanded to further improve the extraction efficiency of carrier in the photovoltaic device.

### SUMMARY OF THE INVENTION

With the foregoing in view, it is a main object of the present invention to further improve the extraction efficiency of carrier in the photovoltaic device.

The present invention is related to a photovoltaic device, comprising: a substrate having a flat surface, a plurality of semiconductor nanowires which are arrayed on the flat surface and tapered from the flat surface to the top and a semiconductor layer, which fills gaps between the plurality of semiconductor nanowires and has a different carrier type from that of the semiconductor nanowires.

### BRIEF DESCRIPTION OF THE DRAWINGS

FIG. 1 is a cross-sectional view depicting an example of a conventional photovoltaic device;

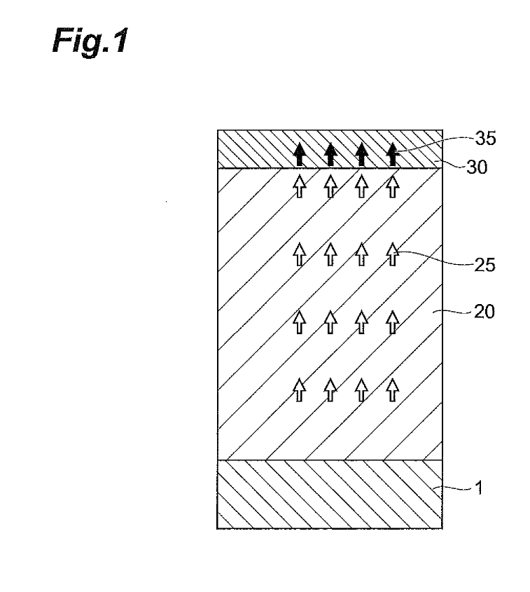

FIG. 2 is a cross-sectional view depicting an example of a conventional photovoltaic device;

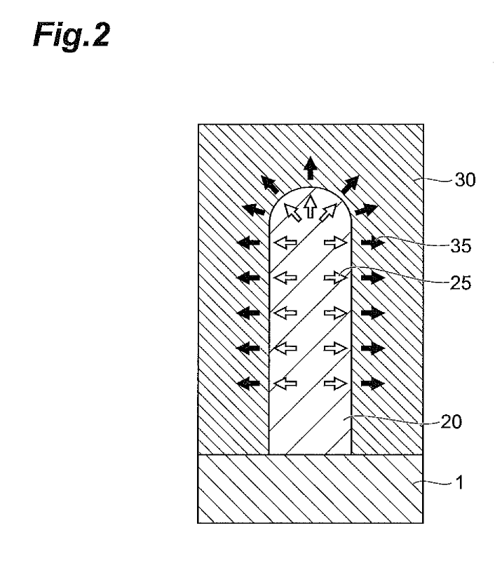

FIG. 3 is a cross-sectional view depicting an embodiment of a photovoltaic device;

FIG. 4 is a diagram depicting a model of a cylindrical semiconductor nanowire;

FIG. 5 is a diagram depicting a model of a tapered semiconductor nanowire;

FIG. 6 is a graph depicting a relationship between a yield of extractable carriers Ys and the length of nanowires;

FIG. 7 is a graph depicting a relationship between a yield of extractable carriers Ys and the length of nanowires;

FIG. 8 is a graph depicting a relationship between a yield of extractable carriers Ys and the length of nanowires;

FIG. 9 is a graph depicting a field of extractable carriers Ys and light absorption coefficients;

FIG. 10 are diagrams depicting an arrayed state of semiconductor wires;

FIG. 11 is a graph depicting the relationship between yield of extractable carriers Ys and the length of nanowires;

FIG. 12 is a graph depicting light absorption coefficients (reference values) of various semiconductor materials;

FIG. 13 is an SEM image of semiconductor nanowires;

FIG. 14 is an EDX spectrum of semiconductor nanowires; and

FIG. 15 is an XRD spectrum of semiconductor nanowires and copper oxide thin film.

### DESCRIPTION OF THE PREFERRED EMBODIMENTS

Preferred embodiments of the present invention will now be described. The present invention, however, is not limited to the following embodiments.

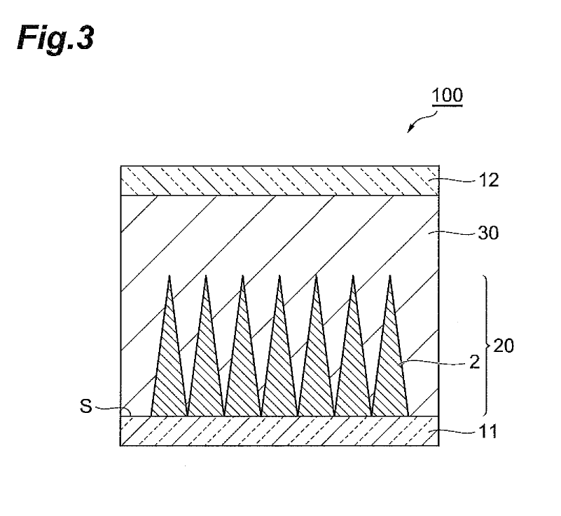

FIG. 3 is a cross-sectional view depicting an embodiment of a photovoltaic device. The photovoltaic device 100 shown in FIG. 3 comprises a transparent conductive substrate 11 which has a flat surface (main surface) S, a p-type semiconductor layer 20 constituted by a plurality of semiconductor nano-wires 2 which are two-dimensionally arrayed on the flat surface S, an n-type semiconductor layer 30 which fills the gaps between the semiconductor nanowires 2 and covers the p-type semiconductor layer 20, and a transparent conductive substrate 12 which is formed on an opposite surface of the semiconductor nanowires 2 of the n-type semiconductor layer 30.

The semiconductor nanowire 2 is a cone having a bottom face contacting the flat surface S and a side face inclined from this bottom face to the tip. In other words, the semiconductor nanowire 2 is tapered from the flat surface S to the tip.

According to the present embodiment, the semiconductor nanowire 2 is comprised of a p-type semiconductor. The light absorption coefficient at 1eV or higher photon energy of semiconductor material which forms the semiconductor nanowire 2, is preferably more than 4×10⁴/cm, and more preferably is more than 5×10⁴/cm. As the later mentioned calculation result shows, if a semiconductor material having a high light absorption coefficient is used, the advantage over cylindrical semiconductor nanowires becomes particularly conspicuous in terms of extraction efficiency of carrier. The upper limit of the light absorption coefficient is not especially limited, but is normally about 1×10⁵/cm. In more concrete terms, it is preferable that this semiconductor nanowire 2 is formed of semiconductor material selected from a group of CIS, CIGS, CZTS, Cu₂O and CdS.

The length of the semiconductor nanowire is preferably more than 500 nm, and more preferably is more than 1 μm. The length of the semiconductor nanowire is preferably less than 10 μm. The radius of the bottom face of the semiconductor nanowire is preferably more than 15 nm. The radius of the bottom face of the semiconductor nanowire is preferably less than 500 nm. If the length and the radius of the bottom face of the semiconductor nanowire are in this range, the effect of extraction efficiency of carrier in the present invention can be exhibited with particular prominence.

In order to achieve higher conversion efficiency, it is preferable that the n-type semiconductor layer 30 is substantially transparent to sunlight. In concrete terms, the n-type semiconductor layer 30 preferably contains at least one semiconductor material selected from ZnO and TiO₂.

The transparent conductive substrates 11 and 12 have a glass substrate and a transparent conductive film formed on the glass substrate respectively, for example. The flat surface S of the transparent conductive substrate 11 is constituted by a transparent conductive film.

Now the results of calculating the yield of extractable carriers in an isolated state will be described for cylindrical semiconductor nanowire and tapered nanowire.

### (1) How to Calculate Yield of Extractable Carriers

When a light with wavelength λ enters semiconductor, the carrier generation rate G at depth z from the incident plane is given by the following expression.

G=αF (1)

In Expression (1), α denotes a light absorption coefficient, and F denotes a photon flux at depth z. F decreases as z increases, and the following expression

$$\frac{d F}{d z} = - α F \qquad ( 2 )$$

is satisfied, and can therefore be expressed as the following expression.

F=F₀exp(−αz) (3)

Here F₀ is flux in the incident plane. Based on Expressions (1) and (3), the carrier generation rate is given by the following expression.

G=αF₀exp(−αz) (4)

### (2) Cylindrical Semiconductor Nanowire

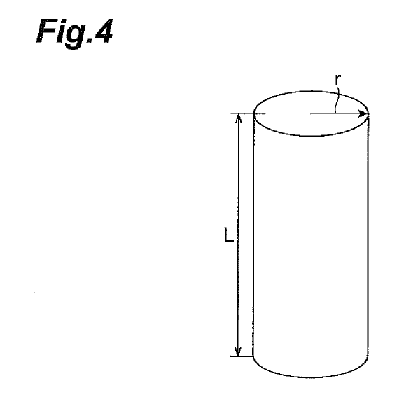

FIG. 4 is a diagram depicting a model of a cylindrical semiconductor nanowire. The model shown in FIG. 4 is a cylinder having radius r of the bottom face and height L. When a light is irradiated onto the top face of the cylinder with photon flux F₀, a number of photons F₀πr² exponentially decreases as the light enters deeper into the nanowire. If it is assumed that one incident photon generates one electron-hole pair, that is, if the quantum efficiency is 100%, then the total number of carriers generated in the nanowire is given by the following expression.

N_{α}=αF₀πr²∫₀^{L}exp(−αz)dz (5)

The generated minority carriers move to a layer constituted by a different type semiconductor material, which is bonded via the surface of the nanowire. If the carrier diffusion length is Sr, the minority carriers move without recombination from a region that is Sr inside from the surface. In other words, by multiplying Expression (5) by a ratio of the volume that contributes to extraction of carrier in the total volume, a number of carriers N_{side}, that can be extracted from the side face, can be given by the following expression.

$${N}_{side} = α {F}_{0} π {r}^{2} {\int }_{0}^{L} exp ( - α z ) d z \frac{{r}^{2} - {( r - δ r )}^{2}}{{r}^{2}} \qquad ( 6 )$$

A number of carriers extracted from the top face of the cylinder can be given by the following expression.

Nₜ=αF₀π(r−δr)²∫₀^{δr}exp(−αz)dz (7)

Based on Expressions (6) and (7), the total number Ns of carriers extracted from both a combination of the top face and side face of the cylinder, namely the number of extractable carrier, is given by the following expressions.

$$\begin{matrix}{N}_{s} = α {F}_{0} π [ \begin{matrix}{r}^{2} {\int }_{0}^{L} exp ( - α z ) d z \frac{{r}^{2} - {( r - δ r )}^{2}}{{r}^{2}} + \\ {( r - δ r )}^{2} {\int }_{0}^{δ r} exp ( - α z ) d z\end{matrix} ] & ( 8 ) \\ {N}_{s} = {F}_{0} π ⌊ \begin{matrix}\{ {r}^{2} - {( r - δ r )}^{2} \} \{ 1 - exp ( - α L ) \} + \\ {( r - δ r )}^{2} \{ 1 - exp ( - α \cdot δ r ) \}\end{matrix} ⌋ & ( 9 )\end{matrix}$$

### (3) Tapered Semiconductor Nanowire

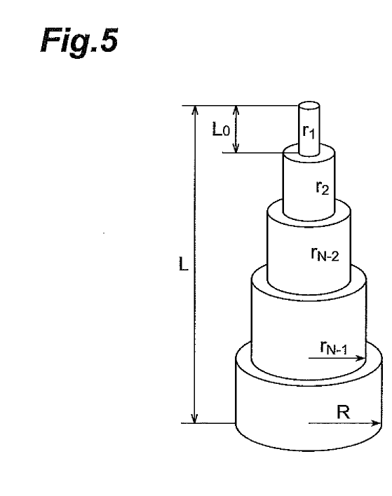

FIG. 5 is a diagram depicting a model of a tapered semiconductor nanowire. The model shown in FIG. 5 has a structure of stacked cylinders with different radii. It is assumed here that the cylinders are referred to as cylinder in the first step, second step, third step . . . from the top. Then the radius rₙ of the cylinder in the nth step is given by the following expression.

$${r}_{n} = \frac{nR}{N} \qquad ( 10 )$$

Here N denotes a total number of steps, and R denotes a radius of a cylinder in the Nth step, that is, in the lowest step.

Just like Expressions (6) and (7), the number of extractable carriers N₁, N₂ and N₃ from the top face and side face in the first step, second step and third step are given by

$${N}_{1} = α {F}_{0} π [ \begin{matrix}{r}^{2} {\int }_{0}^{{L}_{0}} exp ( - α z ) d z \frac{{r}_{1}^{2} - {( {r}_{1} - δ r )}^{2}}{{r}_{1}^{2}} + \\ {( {r}_{1} - δ r )}^{2} {\int }_{0}^{δ r} exp ( - α z ) d z\end{matrix} ]$$

$${N}_{2} = α {F}_{0} π [ \begin{matrix}( {r}_{2}^{2} - {r}_{1}^{2} ) {\int }_{0}^{{L}_{0}} exp ( - α z ) d z \frac{{r}_{2}^{2} - {( {r}_{2} - δ r )}^{2}}{{r}_{2}^{2}} + \\ \{ {( {r}_{2} - δ r )}^{2} - {r}_{1}^{2} \} {\int }_{0}^{δ r} exp ( - α z ) d z\end{matrix} ]$$

$${N}_{3} = α {F}_{0} π [ \begin{matrix}( {r}_{3}^{2} - {r}_{2}^{2} ) {\int }_{0}^{{L}_{0}} exp ( - α z ) d z \frac{{r}_{3}^{2} - {( {r}_{3} - δ r )}^{2}}{{r}_{3}^{2}} + \\ \{ {( {r}_{3} - δ r )}^{2} - {r}_{2}^{2} \} {\int }_{0}^{δ r} exp ( - α z ) d z\end{matrix} ]$$

$$…$$

so the total number of extractable carriers is given by the following expression.

$${N}_{s} = {F}_{0} π [ \begin{matrix}\{ \begin{matrix}{r}_{1}^{2} - {( {r}_{1} - δ r )}^{2} + \\ {\sum }_{n = 2}^{N} \frac{{r}_{n}^{2} - {r}_{n - 1}^{2}}{{r}_{n}^{2}} ( \begin{matrix}{r}_{n}^{2} - \\ {( {r}_{n} - δ r )}^{2}\end{matrix} )\end{matrix} \} \{ 1 - exp ( - α {L}_{0} ) \} + \\ \{ \begin{matrix}{\sum }_{n = 1}^{N} {( {r}_{n} - δ r )}^{2} - \\ {\sum }_{n = 1}^{N - 1} {r}_{n}^{2}\end{matrix} \} \{ 1 - exp ( - α \cdot δ r ) \}\end{matrix} ] \qquad ( 11 )$$

### (4) Result of Calculating Yield of Extractable Carriers (Isolated Nanowire)

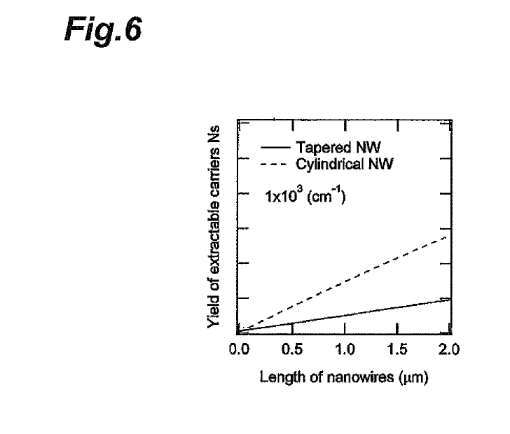

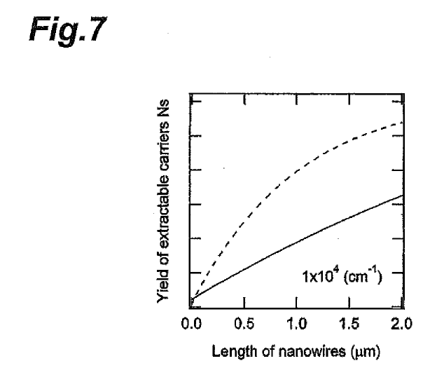

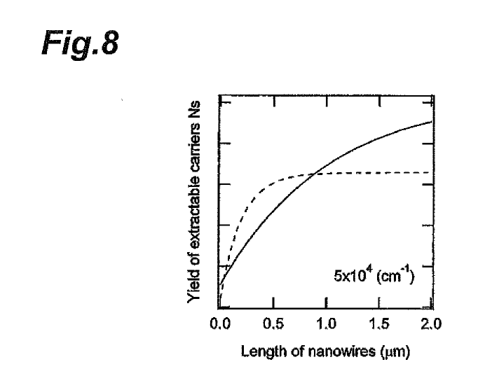

Using Expressions (9) and (11), the yield of extractable carriers Ns, with respect to the length L of an isolated semiconductor nanowire, was calculated. It was assumed that F₀=1, δr=5 nm, N=5, r=r_{N} (=R)=100 nm. FIGS. 6, 7 and 8 are graphs showing the relationship between the yield of extractable carriers Ys and the length L of nanowire. In each graph, the solid line indicates a calculation result of the tapered semiconductor nanowire, and the broken line indicates a calculation result of the cylindrical semiconductor nanowire. In FIGS. 6, 7 and 8, the light absorption coefficients of the semiconductor nanowire are 1×10³/cm, 1×10⁴/cm or 5×10⁴/cm, respectively. As FIG. 8 shows, in the case of the tapered semiconductor nanowire, the yield of extractable carriers Ns is higher than that of the cylindrical nanowire when the length is more than 1 pan and the light absorption coefficient is 5×10⁴/cm.

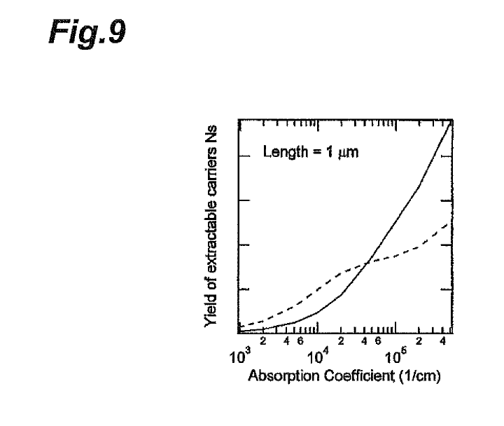

FIG. 9 is a graph depicting the relationship between the yield of extractable carriers Ns and the light absorption coefficient of the semiconductor nanowire when the length of the nanowire is 1 μm. As FIG. 9 shows, the tapered nanowire shows a higher yield of extractable carriers Ns than that of the cylindrical nanowire when the light absorption coefficient is more than 4×10⁴/cm. The effect of the tapered shape becomes prominent when the light absorption coefficient is of the 10⁵/cm order.

### (5) Calculation Result of Yield of Extractable Carriers (Two-Dimensional Array of Nanowire)

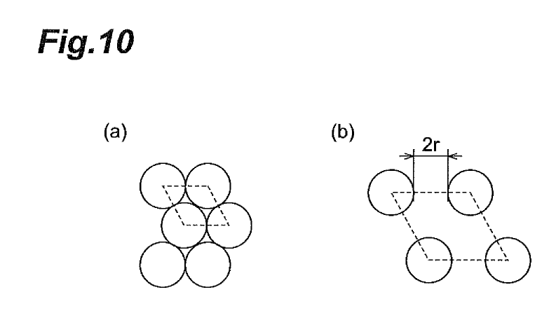

FIG. 10 is a diagram depicting an arrangement of the semiconductor nanowires. FIG. 10 (a) shows a model in an arrangement where the nanowires are closely packed, and FIG. 10 (b) shows a model in an arrangement where the nanowires are arrayed maintaining a gap of 2r. In the case of the cylindrical nanowires, it is practical to use the array maintaining a gap, as shown in (b), since the yield of extractable carriers drops by the contacts of the side faces if the nanowires are closely packed, as shown in (a). In the case of the tapered nanowires, on the other hand, a loss of yield of extractable carriers is very small compared with the cylindrical nanowires, even if the wires are closely packed.

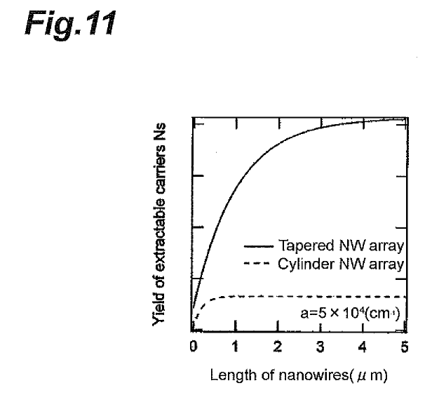

FIG. 11 is a graph depicting the relationship between the yield of extractable carriers Ns and the length L of the nanowire in the case of the tapered nanowires which are closely packed, as shown in the model in FIG. 10 (a), and in the case of the cylindrical nanowires which are arrayed maintaining a gap of diameter (2r), as shown in the model in FIG. 10 (b). The light absorption coefficient is 5×10⁴/cm. As FIG. 11 shows, the tapered nanowires exhibit a higher yield of extractable carriers than the cylindrical nanowires throughout the entire length region. To obtain a same yield of extractable carriers, the tapered nanowire requires only about a ⅓ volume of the cylindrical nanowire. This shows that the present invention will contribute very well to reduce material cost and decrease weight.

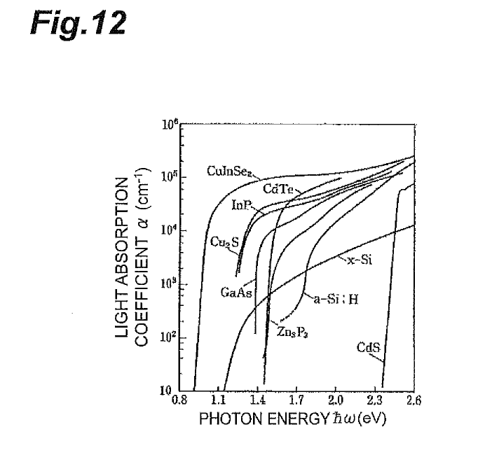

FIG. 12 is a graph showing the light absorption coefficients (reference values) of various semiconductor materials (reference data: Takahiro Wada, “Latest Technology of Compound Thin Film Solar Cells”, CMC Publishing, 2007). As FIG. 12 shows, CIS (CuInSe₂), for example, indicates a 1×10⁵/cm or higher light absorption coefficient. There are many semiconductor materials that indicate a high light absorption coefficient, copper oxide Cu₂O, for example, indicates a high light absorption coefficient, about 10⁴ to 10⁵/cm.

The present invention is not limited to the above mentioned embodiments, but can be modified without departing from the gist of the invention. For example, the tapered semiconductor nanowires may be constituted by an n-type semiconductor material, and a different carrier type (p-type) semiconductor layer may be used to fill in the gaps between the nanowires.

### Examples

The present invention will now be described in more concrete terms using examples. The present invention, however, is not limited to these examples.

Fabricating Semiconductor Nanowire

A 20 mm square copper plate, of which thickness is 1 mm, was cleaned for 20 seconds using 5 mol/L hydrochloric acid, then was immediately inserted into a tube furnace that is heated to 500° C. under atmospheric pressure. The initial copper color turned into dull black after 4 hours of heat treatment.

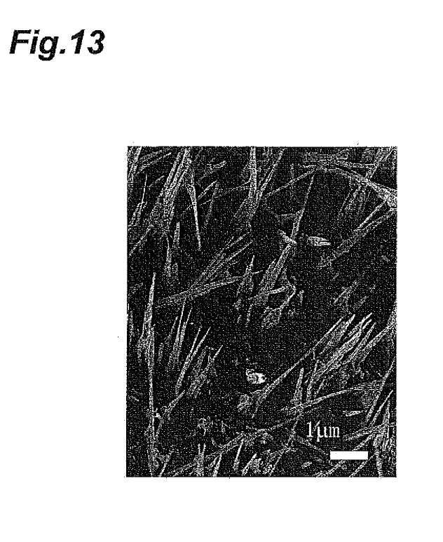

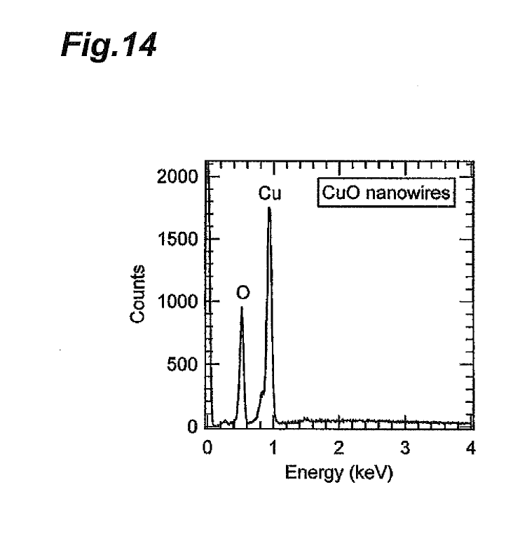

When the surface of the obtained sample was observed under scanning electron microscope (SEM), it was confirmed that tapered copper oxide nanowires have been formed. FIG. 13 is an SEM image of these semiconductor (copper oxide) nanowires. The length of each nanowire is several μm, and the density thereof is about 6×10⁸/cm². FIG. 14 shows the result of composition analysis performed using energy dispersive X-ray analysis (EDX). It was determined that tapered nano-wires are constituted by Cu and O, and has a composition ratio of Cu/O=4/6.

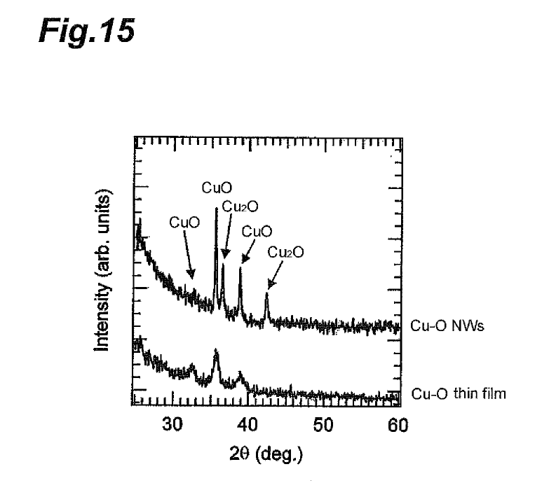

FIG. 15 is an X-ray diffusion (XRD) spectrum of the obtained copper oxide nanowire and copper oxide thin film. The copper oxide thin film is formed by sputtering a target of copper oxide at room temperature, and then heating the film under atmospheric air. It was determined that although the heat treatment temperature is the same for both the nanowire and copper oxide thin film, the nano-wire had a narrower half value width of the peak, and higher crystallization. It was also determined that the nanowire is a complex of Cu₂O and CuO. While the composition ratio obtained by EDX shows oxygen rich, the composition ratio obtained by XRD shows copper rich, and this difference is probably due to the information on amorphous oxide near the substrate during EDX measurement.

According to the photovoltaic device of the present invention, the extraction efficiency of carrier can be further improved. And as a result, further improvement of the photoelectric conversion efficiency is expected.

If the tapered semiconductor nanowires are used, extraction efficiency of carrier, similar to the cylindrical semiconductor nanowires, can be implemented with smaller volume. This contributes to reducing material cost and decreasing weight.

What is claimed is:

1. A photovoltaic device, comprising:
a substrate having a flat surface;
semiconductor nano-wires densely arrayed on the flat surface and tapered from the flat surface;
a semiconductor layer filling gaps between the semiconductor nanowires, and having a different carrier type from that of the semiconductor nanowires.

2. The photovoltaic device according to claim 1, wherein
the semiconductor nanowire is formed of a semiconductor material having a light absorption coefficient of 4×10⁴/cm or higher.

3. The photovoltaic device according to claim 1, wherein
the length of the semiconductor nanowire is 500 nm or more, and the radius of the bottom face of the semiconductor nanowire is 15 nm or more.

4. The photovoltaic device according to claim 1, wherein
the semiconductor layer is transparent to sunlight.
